(19) United States
(12) Patent Application Publication
(10) Pub. No.: US 2003/0207199 A1
(43) Pub. Date: Nov. 6, 2003

(54) Adhesion promoting polymeric materials and planographic printing elements containing them

(75) Inventors: John M. Higgins, Middlesex (GB); Ian M. Newington, Buckinghamshire (GB); Charles C. Anderson, Penfield, NY (US); Harjit S. Bhambra, Leeds (GB); Janglin Chen, Rochester, NY (US)

Correspondence Address: Paul A. Leipold, Patent Legal Staff, Eastman Kodak Company, 343 State Street, Rochester, NY, 14650-2201, US

(73) Assignee: Eastman Kodak Company

(21) Appl. No.: 10/300,345

(22) Filed: Nov. 20, 2002

(30) Foreign Application Priority Data
Nov. 20, 2001 (GB) 0127713.6

(51) Int. Cl. G03F 7/038

(52) U.S. Cl. 430/270.1

(57) ABSTRACT

A planographic printing element suitable to receive and bond with a subsequently applied hydrophilic layer comprises a substrate layer such as polyester film or paper having coated thereon an adhesion layer, said adhesion layer comprising a polymer having a glass transition temperature of less than 15° C. and containing functional groups such as hydroxyl, epoxy or glycidyl capable of reacting with the hydrophilic layer. The polymer may be a terpolymer of a hydroxyalkylacrylate, an alkyl acrylate and an aminoalkylmethacrylate. The polymer may be mixed with gelatin and the mixture applied to the substrate as a coating.

The hydrophilic layer comprising a mixture of alumina and titania particles in a sodium silicate binder is subsequently applied as a coating to the adhesion layer.

### FIELD OF THE INVENTION

This invention relates to planographic printing elements and a method for their preparation.

### BACKGROUND OF THE INVENTION

One form of planographic printing is lithographic printing which relies on the immiscibility of oil and water, wherein the oily material or ink is preferentially retained by the image area of a lithographic printing plate. When a suitably prepared surface is moistened with water and an ink is then applied, the background or non-image area retains the water and repels the ink while the image area accepts the ink and repels the water.

The ink on the image area is then transferred to a surface of a material upon which the image is to be reproduced, such as paper, cloth and the like. Commonly the ink is transferred to an intermediate material called the blanket which in turn transfers the ink to the surface of the material upon which the image is to be reproduced.

The production of printing elements for use in lithographic printing requires the formation of a hydrophilic layer on a substrate.

### PROBLEM TO BE SOLVED BY THE INVENTION

There is a continuing need to improve the adhesion between the hydrophilic layer and the substrate on which it is based. The present invention provides a solution to this problem by providing a planographic printing element in which the hydrophilic layer is bound to the substrate by a selected polymer.

### SUMMARY OF THE INVENTION

According to the present invention there is provided a planographic printing element suitable to receive and bond with a subsequently applied hydrophilic layer said element comprising:

(i) a substrate layer having coated thereon

(ii) an adhesion layer, said adhesion layer comprising a polymer having a glass transition temperature of less than 15° C. and containing functional groups capable of bonding with a hydrophilic layer when the latter is applied as a coating.

### ADVANTAGEOUS EFFECT OF THE INVENTION

By the use of the polymeric layer containing functional groups capable of bonding with groups in the hydrophilic layer, the adhesion of the hydrophilic layer to the substrate is significantly increased and an improved printing element provided.

### BRIEF DESCRIPTION OF THE DRAWINGS

FIG. 1 is a schematic drawing showing a planographic printing element according to the invention.

FIGS. 2 to 5 are graphs which show how the adhesion rating varies with polymer laydown for polymers A,B,C and D.

### DETAILED DESCRIPTION OF THE INVENTION

The term polymer in the present specification is intended to include copolymers and terpolymers unless the context requires otherwise.

The Adhesion Layer

Examples of suitable functional groups contained in the polymer are hydroxyl, epoxy, glycidyl and groups such as halide or sulphonate ester which are capable of being displaced by a nucleophilic group.

Typical functional groups in the hydrophilic layer are —Si—OH, hydroxyl or alkoxide.

The polymer is conveniently obtained by the polymerisation of a monomer containing the functional groups.

The polymers applied as the adhesion layer may comprise latex polymers prepared from monomers containing functional groups that can react with corresponding groups in the hydrophilic layer by either condensation or addition reactions.

Examples of such functional groups include hydroxyl and epoxy, an example of epoxy being a glycidyl group.

The polymer may contain from about 25 to 85 weight %, preferably about 35 to 55 weight % of monomers containing such units.

Suitable polymers are those of hydroxyalkylmethacrylates such as 2-hydroxyethylmethacrylate.

A co-monomer may be employed to assist in obtaining required glass transition temperature of less than 15° C. An example of such a co-monomer is an alkyl acrylate such as butyl acrylate. The co-monomer may be present in amount from 15 to 75 weight %, preferably 45 to 65 weight %.

A further co-monomer may be added to cross-link with gelatin by use of conventional gelatin hardeners (e.g. bis(vinylsulphonyl)methane or the like,) in 0.5-10 weight %, preferably 1 to 7 weight %.

An example of such a co-monomer is an aminoalkyl acrylate such as 2-aminoethyl methacrylate hydrochloride.

The % by weight are based on the combined weight of the monomers present.

A class of preferred polymers are terpolymers of (a) a hydroxyalkylacrylate, (b) an alkyl acrylate and (c) an aminoalkylmethacrylate.

Typical relative amounts of the monomers are: (a) from about 20 to about 80 (b) about 20 to about 70 and (c) from about 2 to about 10.

Another preferred class of polymers are copolymers of (i) glycidyl methacrylate and (ii) an alkyl acrylate.

Typical relative amounts of monomer (i) are from 90 to about 50 of monomer, and monomer (ii) from about 10 to about 50.

The polymers may be prepared by latex or solution polymerisation. Suitable preparations are described in U.S. Pat. No. 4,689,359.

This patent discloses that the adhesion of a coating composition containing gelatin to a discharge treated polyester film support can be improved by incorporating in the gelatin one or more defined polymers. The problem with which this patent is concerned is the bonding of a gelatin-containing composition to a polyester support used for making photographic elements. In contrast, the problem addressed by the present invention is the bonding of the support (which may be polyester) to a hydrophilic layer employed in the preparation of planographic printing elements.

The polymers employed in the present invention may be blended with gelatin and the composition thereby obtained applied as a coating to the substrate.

The polymer/gelatin compositions may have a ratio of polymer to gelatin in the range 95:5 to 5:95 by weight, and more desirably between 95:5 and 40:60.

The laydown of polymer or polymer gelatin composition on the substrate is conveniently at least 50 mg/square metre to 4 g/square metre, preferably from 100 mg/square metre to 500 mg/square metre.

When the polymer is applied with gelatin it is preferred that gelatin provides not more than about 60% by weight of the composition of polymer and gelatin.

Typical thicknesses of the polymer coating are from about 0.05 microns up to about 4 microns.

Such polymer and polymer/gelatin compositions may also include surfactants to provide suitable wetting characteristics, opaque or coloured materials to provide suitable backgrounds, conducting materials to provide anti-static qualities and cross-linking agents to provide sufficient robustness. In addition, materials to adjust pH, particularly to achieve specific conditions intended to facilitate a reaction with an overlying layer, can also be included. These compositions can be coated as a single layer or as a part of multilayer structure.

Suitable polymers and their method of preparation are described in U.S. Pat. Nos. 4,695,532 and 4,689,359.

The Substrate

The substrate may be any one of those known in the planographic printing art. For example the substrate may comprise a polyester film such as polyethylene terephthalate, cellulose acetate film, or other polymer film such as polyethylene or paper such as resin coated paper.

The Hydrophilic Layer

The hydrophilic layer may comprise inorganic oxide particles such as a metal oxide particles, for example aluminium oxide and titanium dioxide together with a binder such as sodium silicate. Suitable hydrophilic layers and their preparation are described in WO 97/19819 and European Patent Application No 963859A the disclosures of which are incorporated by reference.

According to another aspect of the invention a planographic printing element comprises:

(i) a substrate layer having coated thereon

(ii) an adhesion layer comprising a polymer having a glass transition temperature of less than 15° C., said adhesion layer having coated thereon and bonded thereto

(iii) a hydrophilic layer

According to a further aspect of the present invention a method for the preparation of a planographic printing element suitable to receive and bond with a subsequently applied hydrophilic layer comprises:

applying to a substrate a coating of a polymer having a glass transition temperature of less than 15° C. said polymer containing functional groups capable of reacting with corresponding groups in the hydrophilic layer.

Preferably the polymer contains at least 25% by weight of a monomer containing a functional group

The polymer may be applied to the substrate as a composition containing the polymer in admixture with gelatin, preferably in relative amounts of from 95:5 to 5:95 preferably from 95:5 to 40:60 by weight.

In the case of a polyester or similar support, the adhesion of the adhesion layer thereto may be improved by the provision of a layer that provides a key for the adhesion layer, or alternatively, by a surface treatment of the polyester with a corona or glow-discharge as described in U.S. Pat. No. 4,689,359.

The above described method produces a printing element to which a hydrophilic layer will be applied to give a printing element that can be used in planographic printing. Therefore, after the application of the adhesion layer a subsequent step comprises applying a hydrophilic material to the adhesion layer as a coating to form the hydrophilic layer and provide a printing element that can be used in planographic printing.

The invention is illustrated by reference to the following Examples.

All the polymers used in the Examples had a glass transition temperature of less than 15° C.

### EXAMPLE 1

Polymers A and B, shown below, were coated with a suitable coating aid, in this case saponin (which is a surfactant) at approximately 8.5 mg m⁻² of saponin.

Some coatings were composed polymer and saponin and other coatings also contained gelatin.

The coatings were applied onto a polyester support with a pre-applied hard undercoat layer (the purpose of which was to provide a key for the adhesion layer) to give a series of adhesion layers with varying component laydowns.

Polymer A is poly(butyl acrylate-co-2-aminoethyl methacrylate hydrochloride-co-2-hydroxyethylmethacrylate), (50:5:45).

Polymer B is poly(butyl acrylate-co-2-aminoethyl methacrylate hydrochloride-co-2-methoxyethylmethacrylate), (50:5:45).

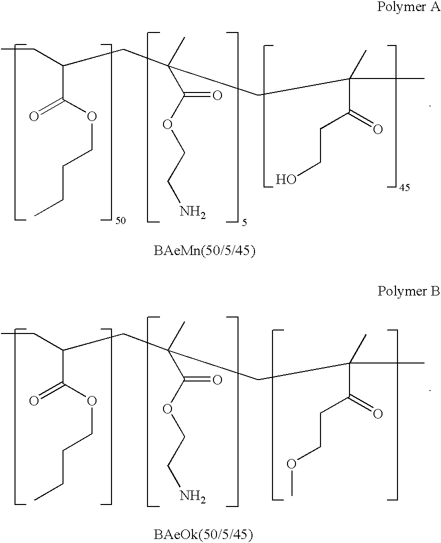

The resulting layers were then overcoated with a hydrophilic layer comprising of a mixture of alumina and titania particles in a sodium silicate binder, in a manner described fully in WO 97/19819, to give a total dry laydown of approximately 10 g m⁻².

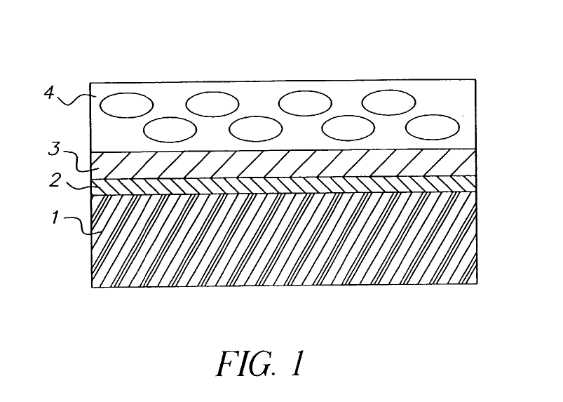

The final coating structure is shown in FIG. 1 below.

FIG. 1 shows an optional hard undercoat layer (2) on the polyester support (1) which has been applied before the adhesion layer (3) to provide a key therefor. The hydrophilic layer (4) is coated over the adhesion layer (3).

An alternative would be to apply the adhesion layer directly onto the bare polyester support after the latter has been treated by corona or glow-discharge as described for example in U.S. Pat. No 4,689,359.

These planographic printing elements were then evaluated for adhesion. The tests were performed by scoring the coatings with a razor blade in a grid pattern (five one inch lines, 0.2 inches apart and another five lines at a 45 degree angle to the first set). A piece of 610 scotch tape (3M company) was applied to the scored area and the tape rapidly peeled off in an effort to remove the hydrophilic layer. The coatings were ranked using a scale of 1 to 6 where 6=Good (no removal of the coating) and 1=Poor (complete removal of the coating).

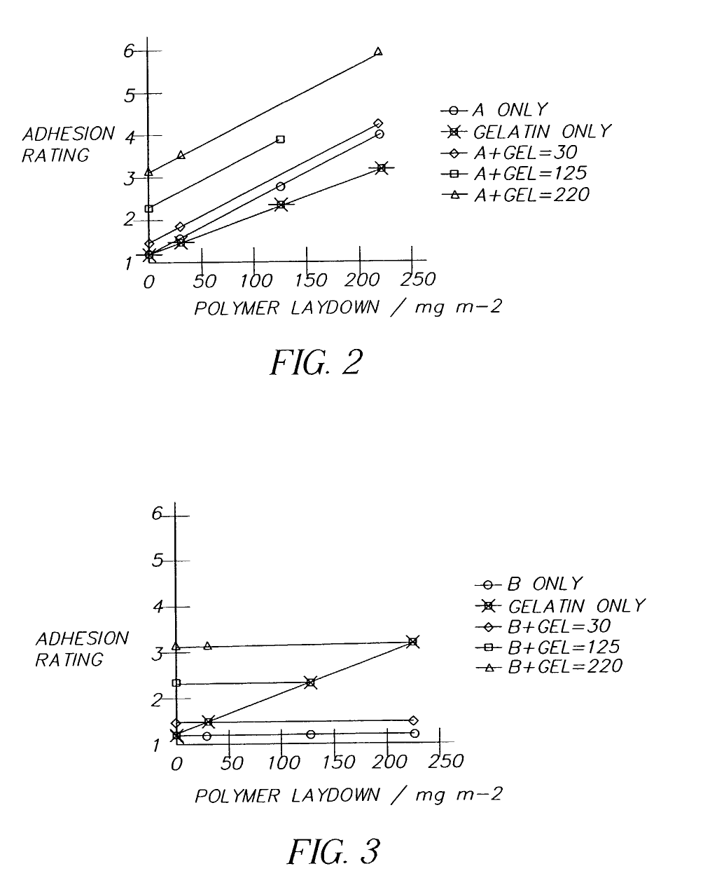

The results obtained from these tests, average values from several coatings, are given in FIGS. 2 and 3.

It can be seen in FIG. 2 that as the laydown of Polymer A was increased the adhesion of the hydrophilic layer increased, producing an effect superior to that obtained with gelatin alone. In addition, it was also possible to coat useful mixtures of Polymer A and gelatin. However FIG. 3 shows that Polymer B (which contains no functional groups capable of bonding with the hydrophilic layer) had no useful effect and also that varying the laydown of polymer B had no discernible effect, even in combination with gelatin.

Polymer B is included for comparative purposes and does not form part of the present invention.

### EXAMPLE 2

Polymers C and D shown below were coated with a suitable coating aid, in this case saponin at approximately 8.5 mg m⁻², and sometimes with gelatin, onto a polyester support with a pre-applied undercoat layer (*) to give a series of adhesion layers with varying component laydowns.

(* It would have been equally possible, but less experimentally convenient, to apply the adhesion layer directly to bare polyester support assisted by corona or glow-discharge treatments as demonstrated in the prior art noted above.)

Polymer C is poly(butyl acrylate-co-2-aminoethyl methacrylate hydrochloride-co-3-chloro-2-hydroxypropyl methacrylate), (50:5:45). Polymer D is poly(glycidyl methacrylate-co-butyl acrylate), (75:25).

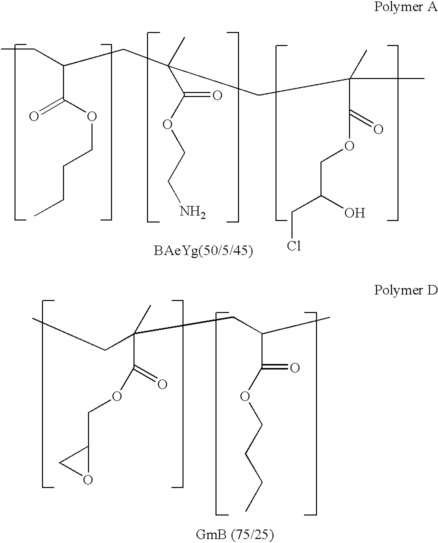

The resulting layers were then overcoated with a hydrophilic layer comprised of a mixture of alumina and titania particles in a sodium silicate binder, in a manner described fully in WO 97/19819, to give a total dry laydown of approximately 10 g m⁻². The final coating structure is given in FIG. 1 above.

These planographic elements were evaluated for adhesion. The tests were performed by scoring the coatings with a razor blade in a grid pattern (five one inch lines, 0.2 inches apart and another five lines at a 45 degree angle to the first set). A piece of 610 scotch tape (3M company) was applied to the scored area and the tape rapidly peeled off in an effort to remove the hydrophilic layer. The coatings were ranked using a scale of 1 to 6 where 6=Good (no removal of the coating) and 1=Poor (complete removal of the coating).

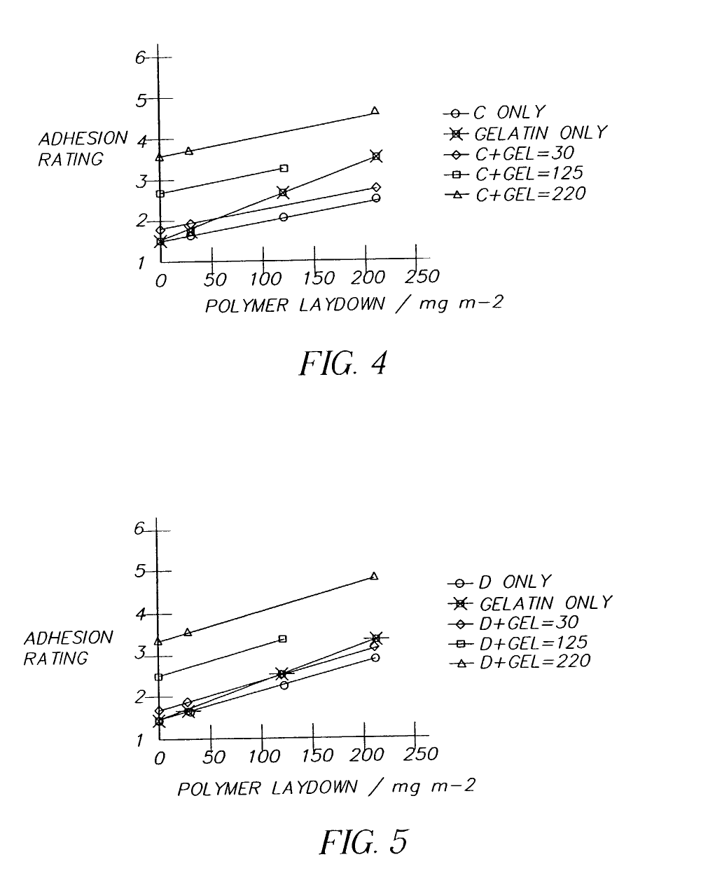

The results obtained from these tests, average values from several coatings, are given in FIGS. 4 and 5 below.

It can be seen in FIG. 4 that as the laydown of Polymer C increased the adhesion of the hydrophilic layer, although the effect was inferior to that obtained with gelatin alone. In addition, it was also possible to coat useful mixtures of Polymer C and gelatin. In the same way, it can be seen in FIG. 5 that as the laydown of Polymer D was increased the adhesion of the hydrophilic layer increased, again, an effect inferior to that obtained with gelatin alone.

As with Polymer C, it was also possible to coat useful mixtures of Polymer D and gelatin.

The invention has been described in detail with particular reference to certain preferred embodiments thereof, but it will be understood that variations and modifications can be effected within the spirit and scope of the invention.

What is claimed is:

1. A planographic printing element suitable to receive and bond with a subsequently applied hydrophilic layer said element comprising:
(i) a substrate layer having coated thereon
(ii) an adhesion layer, said adhesion layer comprising a polymer having a glass transition temperature of less than 15° C. and containing functional groups capable of bonding with a hydrophilic layer when the latter is applied as a coating.

2. A planographic printing element as claimed in claim 1 wherein the functional groups in the polymer are selected from hydroxyl, epoxy and groups capable of being displaced by a nucleophilic group on the hydrophilic layer.

3. A planographic printing element as claimed in claim 2 wherein the polymer contains at least 25% by weight of a monomer containing a functional group.

4. A planographic printing element as claimed in claim 1 wherein the polymer is a copolymer of a monomer (i) containing the functional groups and a monomer (ii) such as an alkyl acrylate in relative amounts such that the glass transition temperature of the copolymer is less than 15° C.

5. A planographic printing element as claimed in claim 4 wherein the amount of monomer (ii) is from 15 to 75% by weight based on the combined weight of the two monomers.

6. A planographic printing element as claimed in claim 4 wherein the polymer is a terpolymer containing a monomer (iii) to provide the capability of crosslinking with gelatin by means of conventional gelatin hardeners.

7. A planographic printing element as claimed in claim 6 wherein the amount of monomer (iii) is from 0.5 to 10% by weight by weight of the combined weights of monomers (i), (ii) and (iii).

8. A planographic printing element as claimed in claim 1 wherein the adhesion layer comprises the polymer and gelatin in relative amounts from 95:5 to 5:95 by weight.

9. A planographic printing element as claimed in claim 1 wherein the laydown of polymer or polymer and gelatin composition is from 50 mg/square metre to 4 g/square metre.

10. A planographic printing element comprising:
(i) a substrate layer having coated thereon
(ii) an adhesion layer, said adhesion layer comprising a polymer having a glass transition temperature of less than 15° C., said adhesion layer having coated thereon and bonded thereto
(iii) a hydrophilic layer.

11. A planographic printing element as claimed in claim 10 wherein the hydrophilic layer comprises metal oxide particles and a silicate binder.

12. A planographic printing element as claimed in claim 11 wherein the metal particles comprise particles of titania and/or alumina.

13. A method for the preparation of a planographic printing element suitable to receive a hydrophilic layer subsequently applied thereto which method comprises
applying to a substrate a coating of a polymer to form an adhesion layer said polymer having a glass transition temperature of less than 15° C. and containing functional groups capable of reacting with corresponding groups in a subsequently applied hydrophilic layer.

14. A method as claimed in claim 13 which further comprises applying a coating of a hydrophilic material to the adhesion layer to form a hydrophilic layer.

15. A method as claimed in claim 14 wherein the hydrophilic layer comprises metal oxide particles and a silicate binder.
